(19) United States
(12) Patent Application Publication
(10) Pub. No.: US 2026/0371639 A1
(43) Pub. Date: Nov. 19, 2026

(54) METHOD AND SYSTEM FOR TRANSFERRING 2D MATERIALS FOR INTEGRATION

(71) Applicant: NEXSTROM PTE. LTD., Singapore (SG)

(72) Inventors: ChengDong Yao, Singapore (SG); Jing-Kai Huang, Singapore (SG); Lain-Jong Li, Singapore (SG)

(21) Appl. No.: 19/680,765

(22) Filed: May 18, 2026

Related U.S. Application Data
(60) Provisional application No. 63/808,352, filed on May 19, 2025.

(51) Int. Cl. H10D 30/47; B32B 7/12; B32B 9/04; B32B 37/00; H10P 90/00

(52) U.S. Cl. CPC H10D 30/481; B32B 7/12; B32B 9/04; B32B 37/025; H10P 90/21; B32B 2457/14

(57) ABSTRACT

A system including a two-dimensional (2D) material, a target substrate, and an adhesive layer are described. The adhesive layer is between the 2D material and the target substrate. The 2D material is transferred from a growth substrate to the target substrate. The 2D material has a first adhesion to the adhesive layer and a second adhesion to the growth substrate. The second adhesion is weaker than the first adhesion.

### CROSS REFERENCE TO OTHER APPLICATIONS

This application claims priority to U.S. Provisional Patent Application No. 63/808,352 entitled METHOD AND SYSTEM FOR TRANSFERRING 2D MATERIALS FOR INTEGRATION filed May 19, 2025 which is incorporated herein by reference for all purposes.

### BACKGROUND OF THE INVENTION

The computing requirements, for example for artificial intelligence (AI) or other applications, are growing rapidly. The growth in the desire for computing power has outpaced even the doubling in density every 2 years described by Moore’s law. Traditionally, integrated circuit density is increased by decreasing the size of a single transistor. However, current technologies are reaching their physical limits. Possible solutions may include new materials and other types of integration. For example, two-dimensional (2D) materials are being developed for use in electronic devices. In addition, density may be improved using three-dimensional (3D) integration.

2D materials are of interest in electronic devices because they exhibit desirable characteristics. Such characteristics include high mobility at the thickness limit of current devices (e.g. high mobility even at thicknesses of 3 nm, 2 nm, 1 nm or below), improved electrostatics, and/or low temperatures used for back end of line (BEOL) processing. Transition metal chalcogenides (TMCs), such as transition metal dichalcogenides (TMDs), are examples of such materials. Thus, 2D TMDs are of particular interest in electronic devices.

However, 2D materials, including 2D TMDs, are often grown on a substrate (a growth substrate) that is appropriate for the high temperature growing conditions, but inappropriate for use in electronic devices. Consequently, techniques for transferring the 2D materials to a target substrate used in electronic devices are desired. However, 2D materials are frequently damaged during transfer. Consequently, techniques for improvements in forming electronic devices from 2D materials such as 2D TMDs are desired.

### BRIEF DESCRIPTION OF THE DRAWINGS

Various embodiments of the invention are disclosed in the following detailed description and the accompanying drawings.

FIGS. 1A-1D are diagrams depicting embodiments of systems including transferred two-dimensional materials.

FIG. 2 is a flow chart depicting an embodiment of a method for providing electronic device using transferred two-dimensional materials.

FIGS. 3A-3F are diagrams depicting embodiments of two-dimensional materials transferred for use in electronic devices during fabrication.

FIGS. 4A-4F are diagrams depicting embodiments of electronic devices formed using transferred two-dimensional materials during fabrication.

FIGS. 5A-5E are diagrams depicting an embodiment of an electronic device formed using transferred two-dimensional materials during fabrication.

FIGS. 6A-6G are diagrams depicting an embodiment of an electronic device formed using transferred two-dimensional materials during fabrication.

FIG. 7 is a flow chart depicting an embodiment of a method for providing electronic device using transferred two-dimensional materials.

FIGS. 8A-8P are diagrams depicting an embodiment of an electronic device formed using transferred two-dimensional materials during fabrication.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Two-dimensional (2D) materials are of interest in electronic devices because they exhibit desirable characteristics. Transition metal chalcogenides (TMCs), such as transition metal dichalcogenides (TMDs), have garnered significant attention in the development of next-generation semiconductor technologies due to their remarkable electrical, optical, and mechanical properties. As used herein, TMC includes both TMDs and TMCs. These materials exhibit unique characteristics such as high carrier mobility, tunable bandgaps, and excellent scalability, making them ideal candidates for a variety of applications, including logic devices, memory devices, electro-optical devices, and flexible electronics. For example, 2D TMCs, such as MoS₂, WSe₂, WS₂, MoTe₂, MoSe₂, SnSe, and SnS, may be semiconductors. Such films, as well as other TMC materials (e.g., TMCs in the form of metals such as WTe₂, TiSe₂), may be used in applications including but not limited to logic devices, memory devices, electro-optic devices (e.g. silicon photonics), and/or flexible devices (e.g., wearables and/or foldable devices). As the semiconductor industry continues to push toward smaller, faster, and more efficient devices, TMCs have emerged as a promising solution for sub-1nm transistors, where traditional silicon-based materials encounter significant limitations. Thus, 2D TMCs are of particular interest in electronic devices.

However, 2D materials, including 2D TMCs, are often desired to be grown on one substrate (a growth substrate) but used with another substrate (e.g., a target substrate). The growth substrate may provide the desired structure for the 2D materials. For example, sapphire has a hexagonal crystal structure and lattice parameter that may be desirable for growth of 2D TMCs. The growth substrate, such as sapphire, may also be capable of withstanding the growing conditions (e.g., being consistent with the desired thermal budget for growth of the desired structure, such as high temperatures of over 600 degrees Celsius) for the 2D materials. However, such substrates may not be conducive to use in electronic devices. Consequently, the 2D materials are desired to be transferred from the growth substrate to the target substrate. However, challenges remain in providing electronic devices using TMCs, particularly 2D TMCs. Such 2D materials are frequently damaged during transfer. Consequently, techniques for improvements in forming electronic devices from 2D materials such as 2D TMCs are desired.

A system including a two-dimensional (2D) material, a target substrate, and an adhesive layer are described. The adhesive layer is between the 2D material and the target substrate. The 2D material is transferred from a growth substrate to the target substrate. The 2D material has a first adhesion to the adhesive layer and a second adhesion to the growth substrate. The second adhesion is weaker than the first adhesion. In some embodiments, the 2D material includes at least one of a transition metal dichalcogenide or a transition metal chalcogenide (e.g., TMC(s)). The growth substrate may include sapphire, while the target substrate may include a silicon wafer. In some embodiments, the adhesive layer includes at least one of an insulator, a metal, a polymer, or a semiconductor. For example, the adhesive layer may include one or more of benzocyclobutene (BCB), amorphous boron nitride (aBN), HfO₂, SiO₂, Al₂O₃, or a metal. In some embodiments, the adhesive layer includes a plurality of layers (e.g., is a multilayer). The adhesive layer may be spun on, deposited on, or grown on the 2D material while the 2D material is on the growth substrate.

In some embodiments, the system also includes an additional adhesive layer on the target substrate. The additional adhesive layer may be spun on, deposited on, or grown on the target substrate. In some embodiments, the adhesive layer and the additional adhesive layer include different materials. In other embodiments, the adhesive layer and the additional adhesive layer include a particular material (e.g., include the same material).

An integrated circuit is described. For example, the integrated circuit may include at least one of a processing unit or a memory. The integrated circuit includes a plurality of electronic devices. Each of the electronic devices includes a source, a drain, and a channel layer for the source and the drain. The channel layer includes (e.g. consists of or has) 2D material. For example, the 2D material may be or include one or more 2D TMCs. An adhesive layer is between the 2D material and a target substrate of the integrated circuit. The 2D material is transferred from a growth substrate to the target substrate. The 2D material has a first adhesion to the adhesive layer and a second adhesion to the growth substrate. The second adhesion is weaker than the first adhesion.

In some embodiments, the target substrate includes a plurality of layers fabricated on an underlying substrate. The adhesive layer may be proximate to a top layer of the plurality of layers such that the 2D material may be bonded to the target substrate using the adhesive layer. In some embodiments, the 2D material includes at least one of a TMD or a TMC (i.e. a 2D TMC). The growth substrate may include sapphire. The adhesive layer may include at least one of benzocyclobutene (BCB), amorphous boron nitride (aBN), HfO₂, SiO₂, Al₂O₃, or a metal.

A method is described. The method includes providing an adhesive layer on a 2D material. The 2D material has been provided on a growth substrate. The method also includes bonding the adhesive layer to a target substrate. The adhesive layer is thus between the 2D material and the target substrate. The 2D material has a first adhesion to the adhesive layer and a second adhesion to the growth substrate. The second adhesion is weaker than the first adhesion. The method also includes removing the growth substrate such that at least a portion of the 2D material is transferred from the growth substrate to the target substrate. In some embodiments, at least 70%, at least 80%, at least 90%, or at least 95% of the 2D material is transferred to the target substrate. The 2D material may include at least one of a TMD or a TMC (e.g., includes one or more TMCs). The growth substrate may include sapphire. The adhesive layer may include at least one of an insulator, a metal, a polymer, or a semiconductor. For example, the adhesive layer may include at least one of BCB, aBN, HfO₂, SiO₂, Al₂O₃, or a metal.

In some embodiments, bonding the adhesive layer further includes bonding the adhesive layer to an additional adhesive layer on the target substrate. Providing the adhesive layer may further includes at least one of spinning, depositing, or growing the adhesive layer on the 2D material while the 2D material is on the growth substrate. Further, the method may include forming at least one electronic device including at least a portion of the 2D material. Although often described in the context of a 2D material and/or a 2D TMC, multiple 2D material(s) and/or multiple 2D TMC(s) may be present.

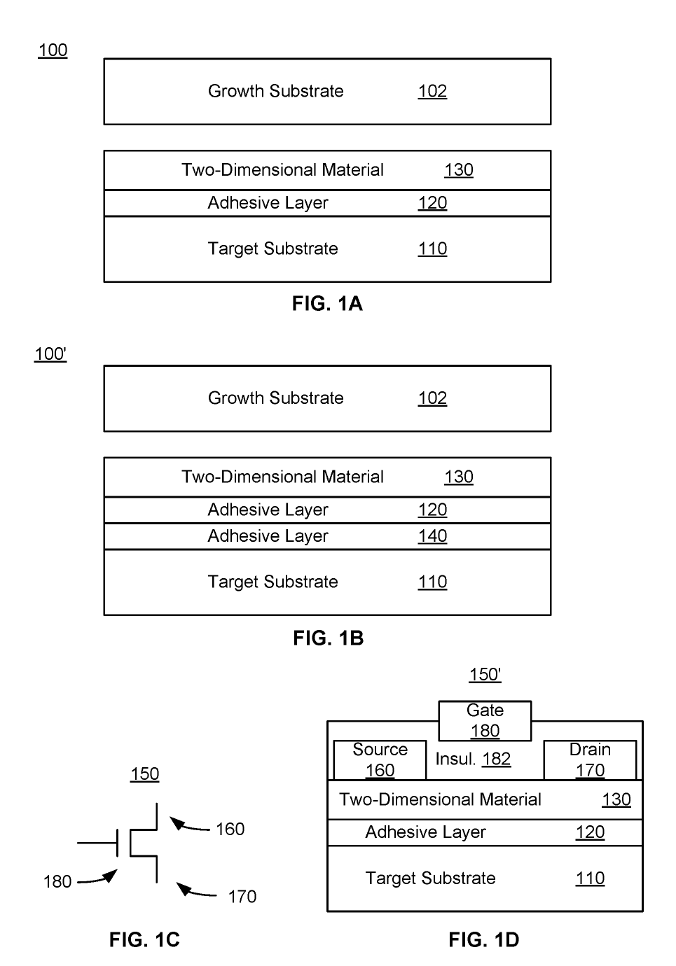

FIGS. 1A-1D are diagrams depicting embodiments of systems 100, 100’, 150, and 150’ including transferred two-dimensional materials. For clarity, FIGS. 1A-1D are not to scale and some components may not be shown. Referring to FIG. 1A, system 100 includes a target substrate 110, an adhesive layer 120, and a 2D material 130. For example, 2D material 130 may be a 2D TMC. As used herein TMC includes transition metal chalcogenides and may include transition metal dichalcogenides (commonly termed TMDs) in some embodiments. For example, the TMC layer may include one or more of MoS₂, WSe₂, WS₂, MoTe₂, MoSe₂, SnSe, SnS, WTe₂, and/or TiSe₂. In some embodiments, 2D material 130 is a TMC layer 130 having a large grain size. For example, 2D material 130 may be characterized by a grain size of at least 5 micrometers, at least ten micrometers, at least twenty micrometers, at least thirty micrometers, at least forty micrometers, or at least fifty micrometers. For example, the grain size may be a few tens of nanometers to at least a few hundred micrometers. 2D material 130 may also be substantially single crystalline (e.g., single grain or merged uni-oriented grains) over at least a portion of target substrate 110. In some such embodiments, 2D material 130 is a TMC layer 130 that is a single crystal. Thus, system 100 may include 2D TMC as or as part of 2D material 130.

Target substrate 110 may be or include a silicon wafer, while growth substrate 102 may be or include sapphire. Target substrate 110 may thus include but may not be limited to silicon (Si), silicon-on-insulator (SOI), glass, polymer, flexible substrates, metal foils, or any substrate comprising dielectric, semiconductor, or conductive layers suitable for integration of 2D materials. Target substrate 110 may optionally include pre-formed device structures, interconnects, and/or additional adhesive layers to facilitate bonding or integration. The target substrate may be planar or non-planar, rigid or flexible.

Also shown in FIGS. 1A and 1B is growth substrate 102 on which 2D material 130 may be grown. Growth substrate 102 is configured to withstand the conditions for fabricating 2D material 130. For example, growth substrate 102 may withstand high temperatures (e.g. 600 degrees Celsius or more) and gases used in fabricating TMCs. Growth substrate 102 may be or include appropriate material(s)/substrate (e.g., insulator, metal, semiconductor) that is bonded with 2D material 130 by a weak force, such as a van der Waals force.

In some embodiments, adhesive layer 120 includes at least one of an insulator, a metal, a polymer, or a semiconductor. For example, layer 120 may include one or more of benzocyclobutene (BCB), amorphous boron nitride (aBN), HfO₂, SiO₂, Al₂O₃, or a metal. In some embodiments, adhesive layer 120 is a multilayer. Adhesive layer 120 may be spun on, deposited on, or grown on 2D material 130 while 2D material 130 is on growth substrate 102. Adhesive layer 120 may form chemical bond(s) with 2D material 130. In some embodiments, 2D material 130 is bonded to adhesive layer 120 by a van der Waals bond. However, this van der Waals bond may be stronger than the bond between 2D material 130 and growth substrate 102. In some embodiments, adhesive layer 120 may undergo chemical mechanical polishing (CMP) or another process to provide the desired flat topography if the surface of adhesive layer 120 is not as desired. In some embodiments, adhesive layer 120 may be at least 0.5 nm thick and not more than 5 micrometers thick.

In some embodiments, 2D material 130 has a stronger adhesion to adhesive layer 120 than to growth substrate 102, regardless of the technique used to provide adhesive layer 120. Thus, 2D material 130 may be separated from growth substrate without significant damage. Further, a larger fraction of 2D material 130 may be removed from growth substrate 102 fully or substantially intact (e.g., as a continuous film). For example, at least 60%, at least 70%, at least 80%, at least 90%, or at least 95% of 2D material 130 may be transferred from growth substrate 102 to target substrate 110. This is true despite the thickness of 2D material 130. For example, 2D material 130 may be a micrometer or less thick. In some embodiments, the 2D material 130 has a thickness of less than about 1 µm, less than 500 nm, less than 100 nm, or less than 10 nm. For example, the thickness of 2D material 130 may be at least 0.3 nm to, e.g., about 10 nm. In some embodiments, the 2D material includes a monolayer, bilayer, few-layer, or multilayer TMC or TMD film.

FIG. 1B depicts system 100’. System 100’ is analogous to system 100. However, adhesive layer 140 is also shown. Adhesive layer 140 may include one or more of BCB, aBN, HfO₂, SiO₂, Al₂O₃, or a metal. In some embodiments, adhesive layer 140 is a multilayer. Adhesive layer 140 may be spun on, deposited on, or grown on target substrate 110. In some embodiments, adhesive layer 140 may be undergo a chemical mechanical polish (CMP) or other process to provide the desired, flat topography if the surface of adhesive layer 140 is not as desired. Adhesive layer 140 may form chemical bond(s) with target substrate 110. Adhesive layer 140 may include the same materials as or different material(s) from adhesive layer 120. In system 100’, adhesive layer 120 is bonded with adhesive layer 140. Thus, adhesive layer 120 may be bonded to target substrate 110 or to an adhesive layer 140 formed on target substrate 110. In some embodiments, adhesive layer 140 may be considered part of target substrate 110.

Thus, 2D material 130 may be grown under the desired conditions to provide the appropriate structure and functions, then transferred to the desired target substrate 110 for use in electronic device. For example, FIGS. 1C and 1D depict portions of electronic devices 150 and 150’ formed using 2D material 130. FIG. 1C depicts a circuit diagram of device 150, while FIG. 1D depicts a cross-sectional view. Thus, electronic devices 150 and 150’ may be transistors. Transistors 150 and 150’ include source 160, drain 170, and gate 180. Also shown in FIG. 1D are gate insulator layers 182, and 2D materials 130 that may be 2D TMC(s). 2D materials 130 may be used in the channel regions of transistors 150 and 150’. Also shown are target substrate 110 and adhesive layer 120.

Thus, in addition to transferring 2D material from growth substrate 102 to target substrate 110, fabrication may continue. As a result, various devices including but not limited to transistors 150 and 150’ may be formed. Thus, the benefits of 2D materials, such as 2D TMCs, may be achieved. In particular, transistors (including 3D transistors) that utilize 2D TMCs may be formed. Both the appropriate growth conditions and the desired substrates for use in electronic devices may be utilized. Consequently, the benefits of 2D materials, such as the high carrier mobility, tunable bandgaps, and excellent scalability of 2D TMCs, may be achieved. Thus, improved logic devices (including processors), memory devices, electro-optic devices, and other electronic devices may be provided.

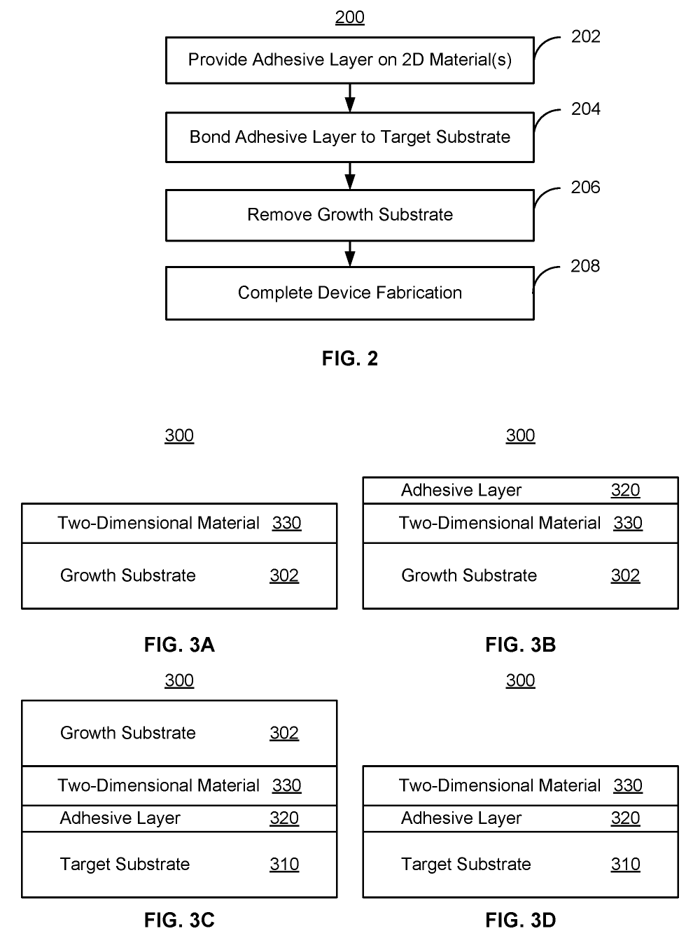

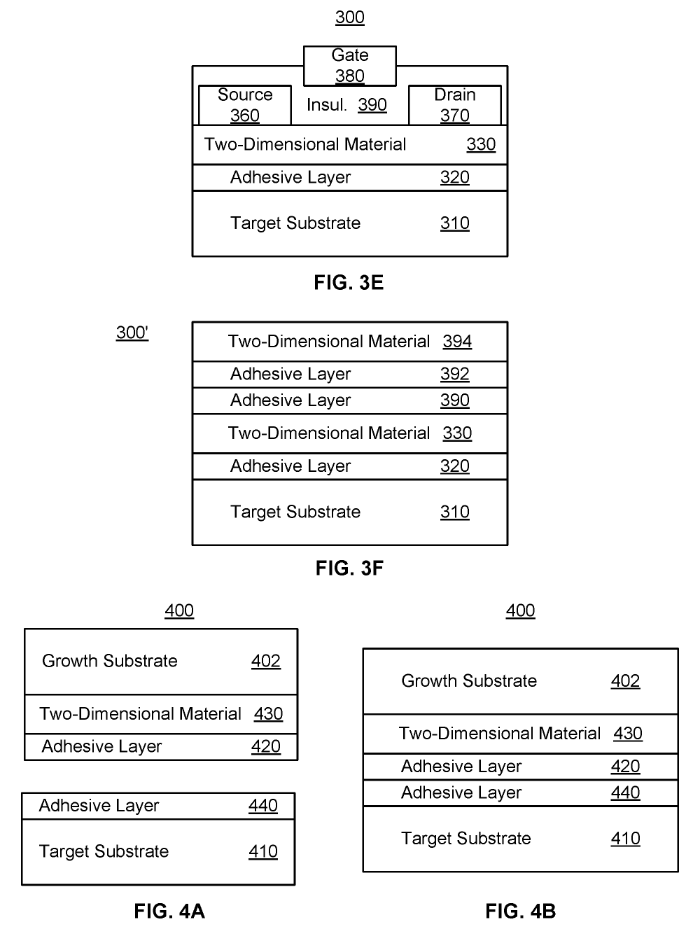

FIG. 2 is a flow chart depicting an embodiment of method 200 for providing an electronic device using transferred 2D materials. For clarity, method 200 is described in the context of FIGS. 3A-3F. However, other electronic devices may be formed in an analogous manner. In addition, multiple devices are generally formed simultaneously. For simplicity, some steps may be omitted or combined. Although described in the context of a particular order, in some embodiments, processes may be performed in another order including but not limited to simultaneously. Method 200 also commences after formation of a 2D material (e.g., 2D TMCs) on a growth substrate. The growth substrate is appropriate for the desired crystal structure of the 2D material as well as the growing conditions. In addition, the growth substrate may be weakly bonded to the 2D material, for example via the van der Waals force.

An adhesive layer is provided on a 2D material grown on the growth substrate, at 202. In some embodiments, the adhesion layer is spun on the 2D material. In some embodiments, the adhesive layer may be deposited or grown on the 2D material. Particularly where deposited or grown, the adhesive layer may include a multilayer. For example, a layer of alumina and a layer of silicon dioxide might be used. The adhesive layer may include at least one of an insulator, a metal, a polymer, or a semiconductor. In some embodiments, providing the adhesive layer may include providing at least one of BCB, aBN, HfO₂, SiO₂, Al₂O₃, or a metal. The 2D material has a first adhesion to the adhesive layer and a second adhesion to the growth substrate. The second adhesion is weaker than the first adhesion. Stated differently, the 2D material will tend to adhere better to the adhesive layer than to the growth substrate.

The adhesive layer (and thus the 2D material and the growth substrate) is bonded to a target substrate, at 204. In some embodiments, 204 utilizes a wafer bonder. The adhesive layer is thus between the 2D material and the target substrate. The target substrate may include but may not be limited to Si (e.g., an Si wafer), SOI, glass, polymer, flexible substrates, metal foils, or any substrate comprising dielectric, semiconductor, or conductive layers suitable for integration of 2D materials. The target substrate may optionally include pre-formed device structures, interconnects, and/or additional adhesive layers to facilitate bonding or integration. The target substrate may be planar or non-planar, rigid or flexible. Further, the adhesive layer has an adhesion to the target substrate that is greater than the adhesion of the 2D material to the growth substrate. In some embodiments, a chemical bond is formed between the adhesion layer and the target substrate. In some embodiments, a van der Waals bond is formed between the adhesion layer and the target substrate. However, this van der Waals bond is stronger than a growth substrate-2D material van der Waals bond.

The method also includes removing the growth substrate, at 206. The growth substrate may be delaminated, etched, or otherwise removed (e.g. by the de-bonder). Thus, at least a portion of the 2D material is transferred from the growth substrate to the target substrate. In some embodiments, at least 70%, at least 80%, at least 90%, or at least 95% of the 2D material is transferred to the target substrate. For example, the growth substrate may be delaminated, polished or otherwise ground down, or etched to be removed.

Fabrication of the electronic device is completed, at 208. For example, the transistors or other structures using the 2D material(s) may be formed. In addition, other 2D materials may be transferred to the device for subsequent layers as part of 208. Thus, the desired electronic device(s) may be formed.

Thus, method 200 describes techniques for a clean transfer of 2D materials, such as 2D TMCs. The techniques of method 200 may transfer 2D materials from a growth substrate to another substrate with high integrity. Thus, little damage to the 2D material may occur and/or a high fraction of the 2D material (e.g. ninety percent or above) may be transferred. Thus, the 2D materials may be used in electronic devices. Further, method 200 may transfer the 2D material to various locations in the electronic devices. As a result, the three-dimensional integration of 2D materials can be realized. The transfer includes depositing, spin-coating, or otherwise providing adhesive material on 2D materials and, in some embodiments, the target substrate. The 2D materials are bonded to the target substrate via the adhesive layer(s). Devices, e.g. with top gates, are fabricated based on the transferred 2D materials.

For example, FIGS. 3A-3F are diagrams depicting an embodiment of devices 300 and 300’ including a two-dimensional material transferred for use in electronic devices during fabrication. For clarity, FIGS. 3A-3F are not to scale and some components may not be shown. FIGS. 3A-3F may be considered to depict formation of devices 300 and 300’ using method 200. FIG. 3A depicts 2D material 330 on growth substrate 302. Growth substrate 302 may be analogous to growth substrate 102. In some embodiments, 2D material is a 2D TMC that may have the properties (e.g., thickness, grain size, and/or electrical properties) described herein. Thus, 2D material 330 is analogous to 2D material 130.

FIG. 3B depicts electronic device 300 after adhesive layer 320 has been formed at 202. Thus, adhesive layer 320 may have been spin coated or otherwise formed on 2D material 330. Adhesive layer 320 may be analogous to adhesive layer 120. FIG. 3C depicts electronic device 300 after bonding to target substrate 310. Substrate 310 is analogous to substrate 110. FIG. 3D depicts electronic device 300 after growth substrate 302 has been decoupled from 2D material 330. FIG. 3E depicts electronic device 300 after formation of electronic device 300 is at least partially completed. Thus, a transistor analogous to transistors 150 and 150’ may be formed. Thus, source 360, drain 370, gate insulator 390, and gate 380 are formed. Source 360, drain 370, gate insulator 390, and gate 380 that are analogous to source 160, drain 170, gate insulator 182, and gate 180, respectively. Additional structures may also be formed. For example, contacts to gate 380, source 360, and/or drain 370, other metallization, other insulation and/or other features may be provided. FIG. 3F depicts another device 300’ in which formation of the device in 208 continued in a different manner than for device 300. Device 300’ includes target substrate 310, adhesive layer 320, and 2D material 330, which are analogous to device 300. However, for device 300, 208 includes iterating 202, 204, and 206, plus providing adhesive layer 390 on 2D material 330. Thus, device 300’ includes adhesive layer 392 and 2D material 394 that are analogous to adhesive layer 320 and 2D material 330. 2D material 394 may be the same as or different from 2D material 330. The growth substrate (not shown) has already been removed. Additional 2D layer(s) (as well as adhesive layer(s)) may be provided in a similar manner. In some embodiments, adhesive layer 390 or 392 may be omitted. Thus, a multilayer, or superlattice, that includes multiple 2D layers 330 and 394 may be provided. In some embodiments, the repeated 2D material/adhesive stack of device 300’ may be used as an intermediate structure for three-dimensional integration, stacked electronic devices, stacked optical devices, and/or multilayer memory structures. Although not shown, other components, such as transistors, may also be formed.

Thus, electronic devices 300 and 300’ may be formed. Electronic devices 300 and 300’ may include both 2D materials (e.g. 2D TMCs) and the desired target substrate 310. Consequently, performance of electronic devices 300 and 300’ may be improved.

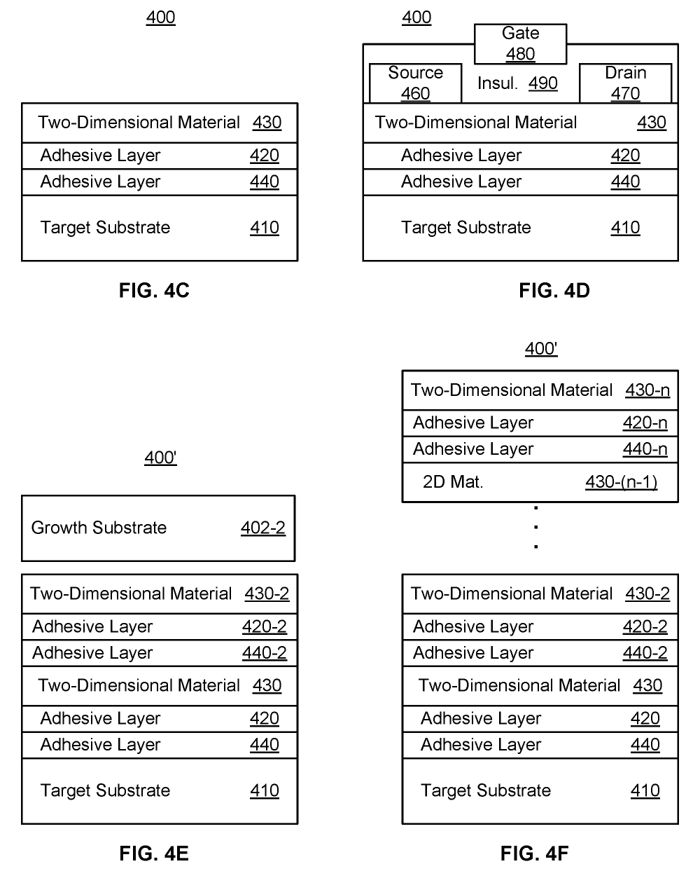

FIGS. 4A-4F are diagrams depicting embodiments of electronic devices 400 and 400’ formed using transferred two-dimensional materials during fabrication. For clarity, FIGS. 4A-4F are not to scale and some components may not be shown. FIGS. 4A-4F may be considered to depict formation of devices 400 and 400’ using method 200.

FIG. 4A depicts electronic device 400 after adhesive layer 420 has been formed at 202. Thus, 2D material 430 has been provided on growth substrate 402. Growth substrate 402 may be analogous to growth substrate 102. In some embodiments, 2D material is a 2D TMC that may have the properties (e.g., thickness, grain size, and/or electrical properties) described herein. Thus, 2D material 430 is analogous to 2D material 130. Adhesive layer 420 may have been spin coated or otherwise formed on 2D material 430. Adhesive layer 420 may be analogous to adhesive layer 120. FIG. 4B depicts electronic device 400 after bonding to target substrate 410. Substrate 410 is analogous to substrate 110. However, an additional adhesive layer 440 is explicitly included. Adhesive layer 440 may be analogous to adhesive layer 140. FIG. 4C depicts electronic device 400 after growth substrate 402 has been decoupled from 2D material 430. FIG. 4D depicts electronic device 400 after formation of electronic device 400 is at least partially completed. Thus, a transistor analogous to transistor 150 and 150’ may be formed (given that adhesive layer 440 might be considered to be part of the target substrate). Thus, source 460, drain 470, gate insulator 490, and gate 480 are formed. Source 460, drain 470, gate insulator 490, and gate 480 that are analogous to source 160, drain 170, gate insulator 182, and gate 180, respectively. Additional structures may also be formed. For example, contacts to gate 480, source 460, and/or drain 470, other metallization, other insulation and/or other features may be provided.

FIGS. 4E-4F depicts another device 400’ in which formation of the device in 208 continued in a different manner than for device 400. Device 400’ includes target substrate 410, adhesive layer 420, and 2D material 430, which are analogous to device 400. However, FIG. 4E depicts device 400’ where 208 includes iterating 202, 204, and 206, plus providing adhesive layer 440-2 on 2D layer 430. Also shown is growth substrate 402-2 just after separation from device 400’. Growth substrate 402-2 may be analogous to growth substrate 402. Thus, device 400’ includes adhesive layers 440-2 and 420-2 and 2D material 430-2 that are analogous to adhesive layers 440 and 420 and 2D material 430.

FIG. 4F depicts device 400’ after multiple iterations of 202, 204, and 206 have been performed. Thus, device 400’ includes n 2D layers separated by n bilayers of adhesive 440-i and 420-i, where i goes from 2 through n. In some embodiments, adhesive layer 420-i or 440-i may be omitted. 2D material 430-i may be the same as or different from 2D material 430 or another layer of 2D material 430-j. Adhesive layers 420-i and 440-i may be the same as or different from adhesive layers 420 and 440 or other adhesive layers 420-j and 440-j. Thus, a multilayer, or superlattice, that includes multiple 2D layers 430 and 430-i may be provided. In some embodiments, the repeated 2D material/adhesive stack of device 400’ may be used as an intermediate structure for three-dimensional integration, stacked electronic devices, stacked optical devices, and/or multilayer memory structures. Although not shown, other components, such as transistors, may also be formed.

Thus, electronic devices 400 and/or 400’ may be formed. Electronic devices 400 and 400’may include both 2D materials (e.g. 2D TMCs) and the desired target substrate 410. Consequently, performance of electronic device 400 may be improved.

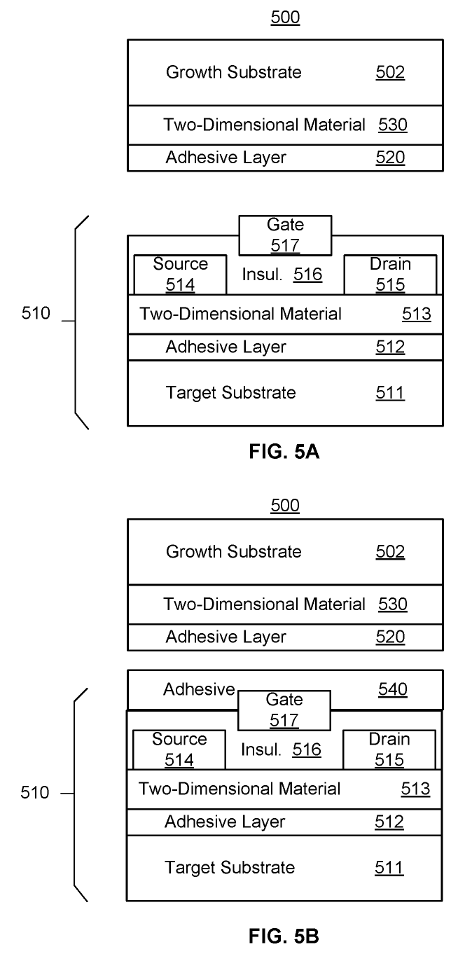

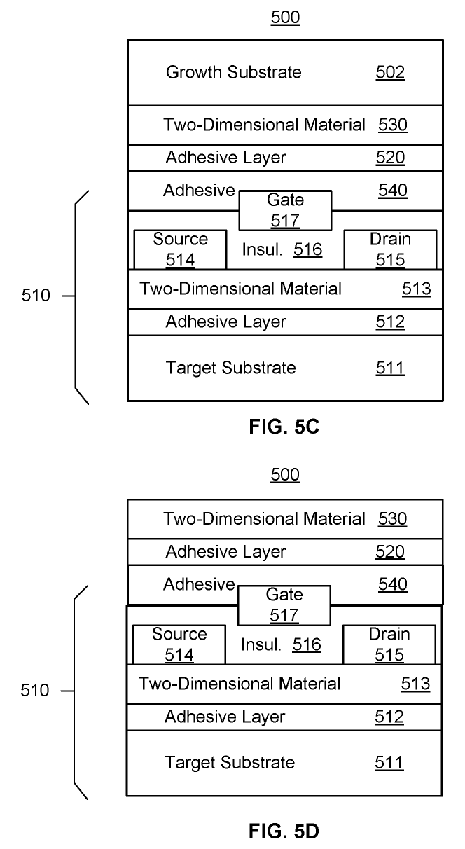

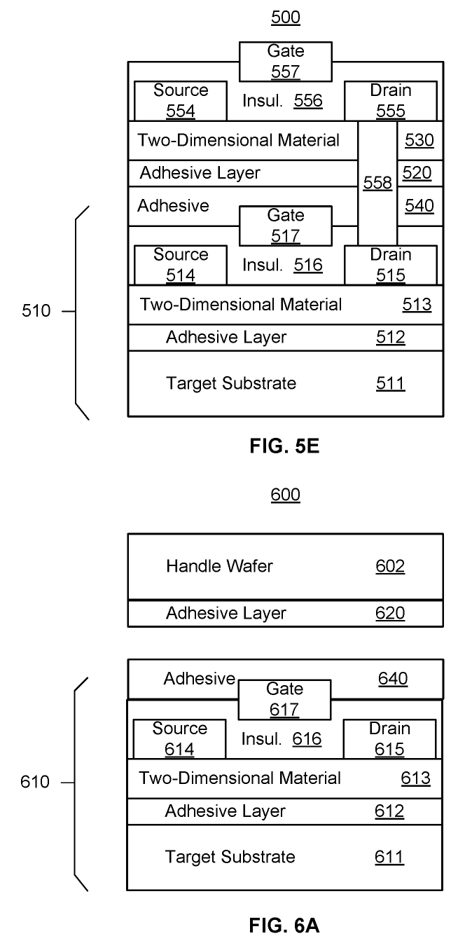

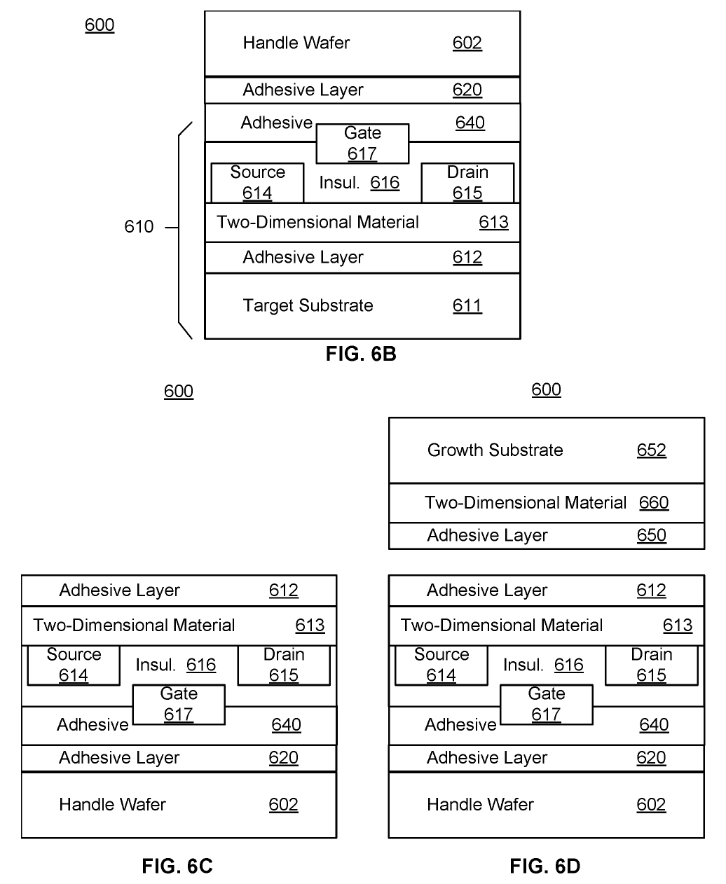

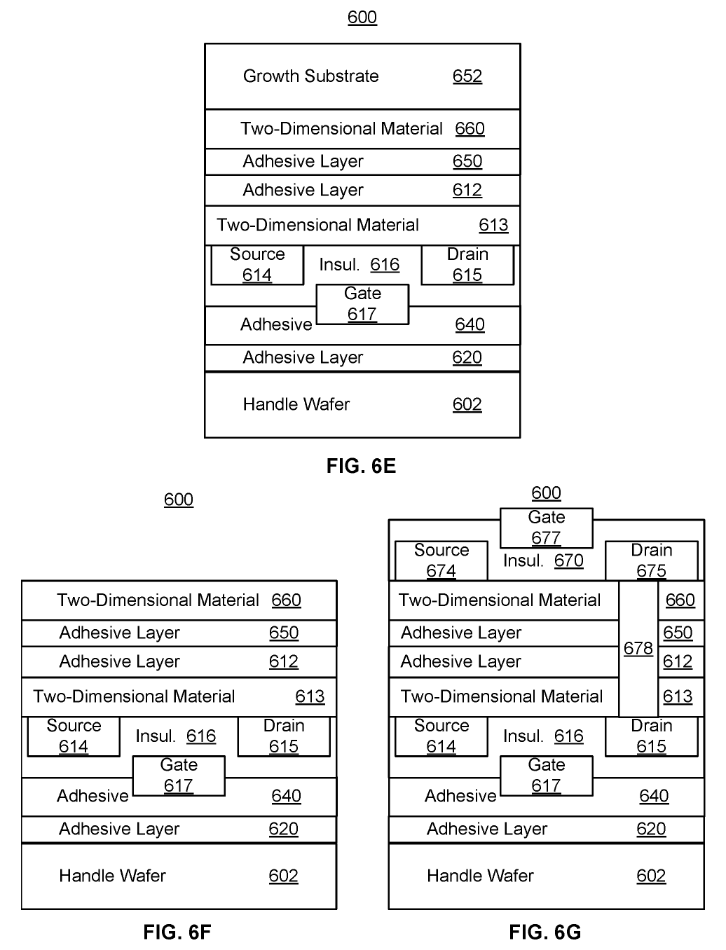

The process 200 and devices 300 and 400 of FIGS. 2, 3A-3E, and 4A-4E may be incorporated into electronic devices in various manners and for a variety of architectures. Some such electronic devices and techniques are depicted in and described in the context of FIGS. 5A-6G. Thus, FIGS. 5A-6G depict embodiments of devices including structures analogous to those depicted in FIGS. 1A-1D, 3A-3E, and/or 4A-4D.

FIGS. 5A-5E are diagrams depicting an embodiment of electronic device 500 formed using transferred 2D materials during fabrication. For clarity, FIGS. 5A-5E are not to scale and some components may not be shown. FIGS. 5A-5E may be considered to depict formation of device 500 using method 200. In particular, the electronic device may be formed (e.g. at 208 of method 200) using other portions of method 200 (e.g., 202, 204, and/or 206). Thus, 2D materials may be integrated into the desired structure layer-by-layer.

FIG. 5A depicts 2D material 530 on growth substrate 502 an adhesive layer 520 has been provided. Growth substrate 502 may be analogous to growth substrate 102. In some embodiments, 2D material is a 2D TMC that may have the properties (e.g., thickness, grain size, and/or electrical properties) described herein. Thus, 2D material 530 is analogous to 2D material 130. Adhesive layer 520 may be analogous to adhesive layer 120. Thus, adhesive layer 520 may have been spin coated or otherwise provided on 2D material 530. Also shown is target substrate 510. Target substrate 510 includes multiple components including substrate 511, which may be a silicon wafer, SOI, or other substrate analogous to target substrate 110. Target substrate 510 also includes adhesive layer 512, 2D material 513, source 514, drain 515, gate insulator 516, and gate 517 that may be analogous to adhesive layer 120, 2D material 130, source 160, drain 170, gate insulator 182, and gate 180, respectively. Thus, 2D layer 530 is desired to be integrated into a higher layer of device 500 being fabricated.

FIG. 5B depicts device 500 after adhesive layer 540 has been provided. Adhesive layer 540 may be analogous to adhesive layer 140. Thus, adhesive layer 540 has been spun on or otherwise provided on multilayer/multi-component target substrate 510. In addition, the surface(s) of adhesive layer(s) 520 and/or 540 may be planarized (e.g., via CMP) if the surfaces are not as even as desired. In some embodiments, other and/or additional structures may be present. In some embodiments, adhesive layer 540 may be considered part of target substrate 510.

FIG. 5C depicts device 500 after 2D material 530 has been bonded to target substrate 510. More specifically, adhesive layer 520 has been bonded to adhesive layer 540. In some embodiments, this occurs via a wafer bonder. FIG. 5D depicts device 500 after growth substrate 502 has been delaminated, or removed. Thus, additional components using 2D material 530 may be formed as part of electronic device 500. For example, FIG. 5E depicts electronic device 500 after an additional transistor including source 554, drain 555, gate insulator 556, and gate 557 have been formed. Also shown is conductive via 558 between drains 555 and 515. Source 554, drain 555, gate insulator 556, and gate 557 may be analogous to source 514, drain 515, gate insulator 516, and gate 517. Electronic device 500 includes multiple layers having 2D materials 530 and 513.

Thus, method 200 may be used to provide device 500 that incorporates 2D materials 513 and 530, such as 2D TMCs, layer-by-layer. At each subsequent layer, the remaining portion of the device that has already been fabricated may be considered to be a new target substrate. Adhesive layer 540 provided on target substrate 510 may be used to planarize the top surface of target substrate 510 as well as to bond to adhesive layer 520. In some embodiments, adhesive layer 540 may be omitted. Because multiple layers of components of electronic device 500 may include TMCs, performance of multiple layers of components of electronic device 500 may be improved.

FIGS. 6A-6G are diagrams depicting an embodiment of electronic device 600 formed using transferred two-dimensional materials during fabrication. More specifically, FIGS. 6A-6G indicate the use of flip-chip technology in conjunction with 2D materials. For clarity, FIGS. 6A-6G are not to scale and some components may not be shown. FIGS. 6A-6G may be considered to depict formation of device 600 using method 200. In particular, the electronic device may be formed (e.g. at 208 of method 200) using other portions of method 200 (e.g., 202, 204, and/or 206). Thus, 2D materials may be integrated into the desired flip-chip structure layer-by-layer.

FIG. 6A depicts adhesive layer 620 on handle wafer 602. Adhesive layer 620 may be analogous to adhesive layer 120. Thus, adhesive layer 620 may have been spin coated or otherwise provided on handle wafer 602. In some embodiments, other adhesive layer(s) may be used. Also shown is target substrate 610. For clarity, target substrate 610 is only labeled in FIGS. 6A and 6B. Target substrate 610 includes multiple components including substrate 611, which may be a silicon wafer, SOI, or other substrate analogous to target substrate 110. Target substrate 610 also includes adhesive layer 612, 2D material 613, source 614, drain 615, gate insulator 616, and gate 617 that may be analogous to adhesive layer 120, 2D material 130, source 160, drain 170, gate insulator 182, and gate 180, respectively. Also shown is adhesive layer 640. Adhesive layer 640 may be analogous to adhesive layer 140. Thus, adhesive layer 640 has been spun on or otherwise provided on multilayer/multi-component target substrate 610. In addition, the surface(s) of adhesive layer(s) 620 and/or 640 may be planarized (e.g., via CMP) if the surfaces are not as even as desired. In some embodiments, other and/or additional structures may be present. In some embodiments, adhesive layer 640 may be considered part of target substrate 610.

FIG. 6B depicts device 600 after adhesive layer 620 has been bonded to target substrate 610. More specifically, adhesive layer 620 has been bonded to adhesive layer 640. In some embodiments, this occurs via a wafer bonder. FIG. 6C depicts device 600 after handle wafer 602 has been delaminated, or removed. In addition, the target substrate has been flipped. Thus, adhesive layer 612 forms the top surface.

Additional components using 2D materials may still be incorporated into flip-chip device 600. For example, FIG. 6D depicts electronic device 600 in conjunction with an additional growth substrate 652, 2D material 660, and adhesive layer 650. Growth substrate 652, 2D material 660, and adhesive layer 650 are analogous to growth substrate 102, 2D material 130, and adhesive layer 120. Thus, 2D material 660 may be or include 2D TMC(s).

FIG. 6E depicts electronic device 600 after 2D material has been bonded to target substrate 610. More specifically, adhesive layer 650 is bonded to adhesive layer 612. This may occur using a wafer bonder. FIG. 6F depicts electronic device 600 after growth substrate 652 has been removed.

FIG. 6G depicts electronic device 600 after an additional transistor including source 674, drain 675, gate insulator 670, and gate 677 have been formed. Also shown is conductive via 678 between drains 675 and 615. Source 674, drain 675, gate insulator 670, and gate 677 may be analogous to source 614, drain 615, gate insulator 516, and gate 617. Electronic device 600 includes multiple layers having 2D materials 630 and 613.

Thus, method 200 may be used to provide device 600 that incorporates 2D materials 613 and 660, such as 2D TMCs, layer-by-layer. Moreover, flip-chip technology has been used. At each subsequent layer, the remaining portion of the device that has already been fabricated may be considered to be a new target substrate. Adhesive layer 640 provided on target substrate 610 may be used to planarize the top surface of target substrate 610 as well as to bond to adhesive layer 620. In some embodiments, adhesive layer 640 may be omitted. Because multiple layers of components of flip-chip electronic device 600 may include TMCs, performance of multiple layers of components of electronic device 600 may be improved.

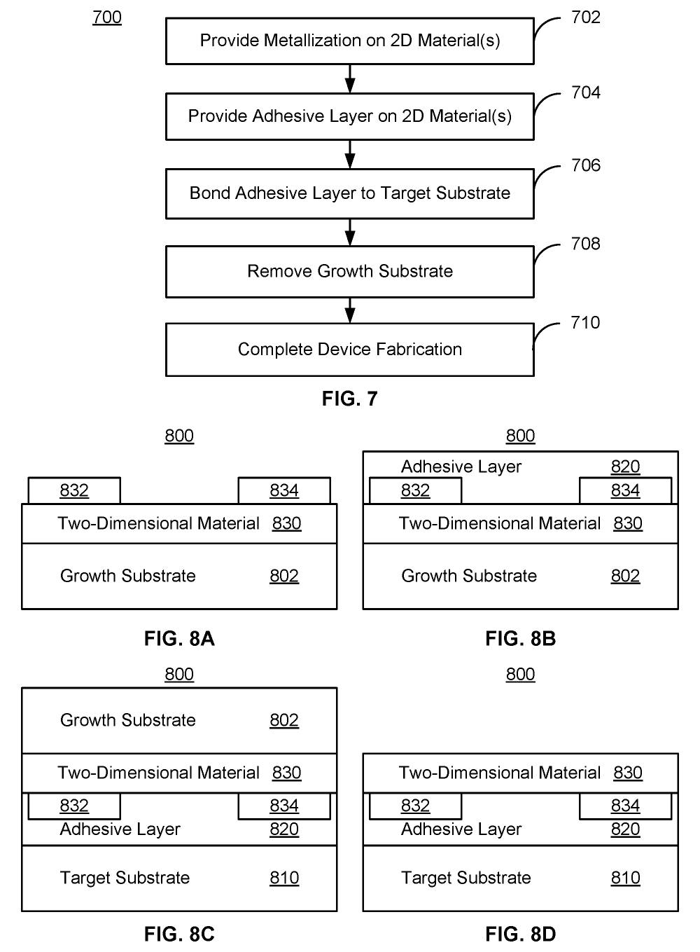

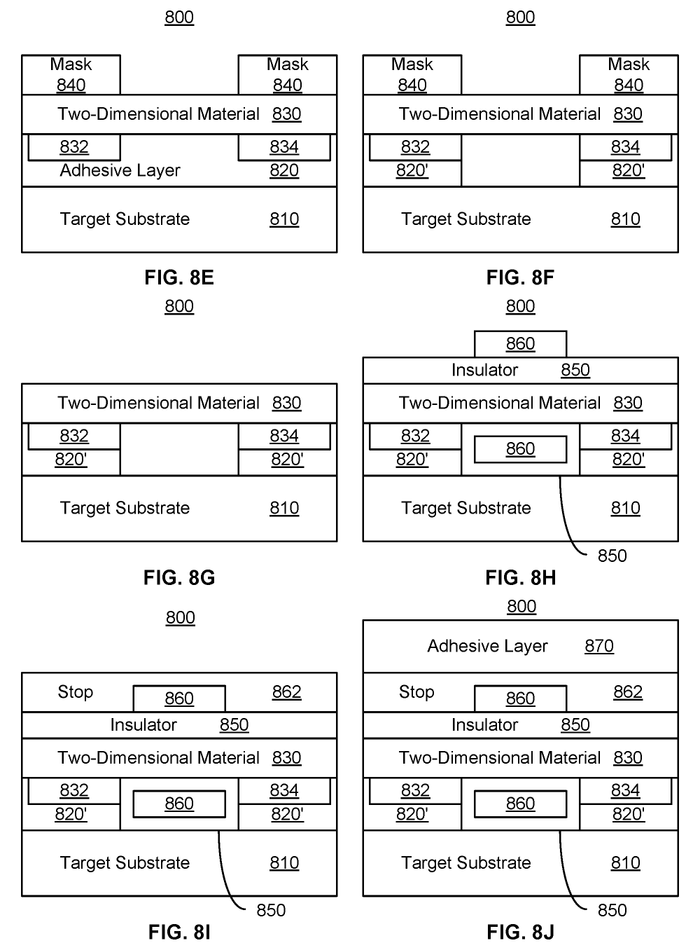

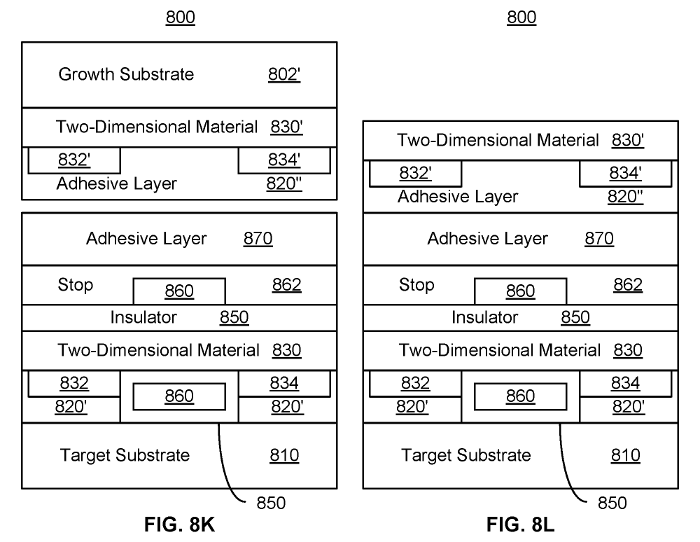

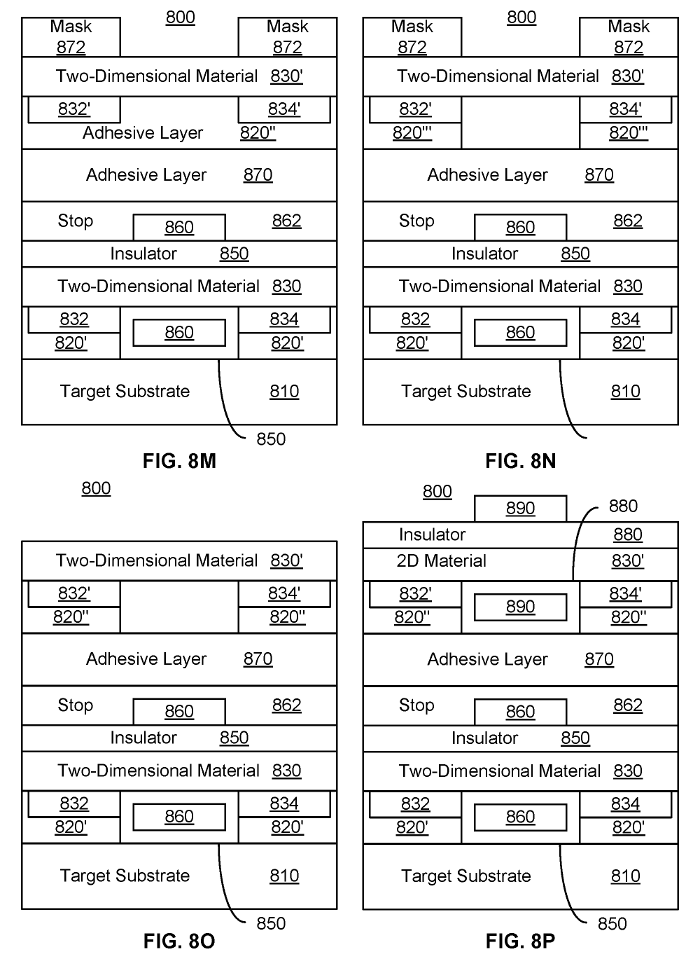

FIG. 7 is a flow chart depicting an embodiment of method 700 for providing electronic device using transferred 2D materials. More specifically, method 700 may be used to provide a three-dimensional (3D) electronic device: a gate all around structure. Method 700 may be extended For clarity, method 700 is described in the context of FIGS. 8A-8P. However, other electronic devices may be formed in an analogous manner. In addition, multiple devices are generally formed simultaneously. For simplicity, some steps may be omitted or combined. Although described in the context of a particular order, in some embodiments, processes may be performed in another order including but not limited to simultaneously. Method 700 also commences after formation of a 2D material (e.g., 2D TMC(s)) on a growth substrate. The growth substrate is appropriate for the desired crystal structure of the 2D material as well as the growing conditions. In addition, the growth substrate may be weakly bonded to the 2D material, for example via the van der Waals force.

Metallization for the electronic device is provided on the 2D material(s) residing on the growth substrate, at 702. For example, the 2D material may be masked, the metal deposited, and the mask lifted off. An adhesive layer is provided on a 2D material grown and metal, at 704. In some embodiments, the adhesion layer is spun on the 2D material. In some embodiments, the adhesion layer may be deposited or grown on the 2D material. Particularly where deposited or grown, the adhesive layer may include a multilayer. For example, a layer of alumina and a layer of silicon dioxide might be used. The adhesive layer may include at least one of an insulator, a metal, a polymer, or a semiconductor. In some embodiments, providing the adhesive layer may include providing at least one of BCB, aBN, HfO₂, SiO₂, Al₂O₃, or a metal. The 2D material has a first adhesion to the adhesive layer and a second adhesion to the growth substrate. The second adhesion is weaker than the first adhesion. Stated differently, the 2D material will tend to adhere better to the adhesive layer than to the growth substrate. Further, the adhesive layer provided at 704 may be configured to provide a smooth surface for bonding to the target substrate. In some embodiments, a CMP or other planarization step may be used to provide a flat surface.

The adhesive layer (and thus the 2D material and the growth substrate) are bonded to a target substrate, at 706. In some embodiments, 706 utilizes a wafer bonder. The adhesive layer is thus between the 2D material and the target substrate. The target substrate may include but may not be limited to Si (e.g., an Si wafer), SOI, glass, polymer, flexible substrates, metal foils, or any substrate comprising dielectric, semiconductor, or conductive layers suitable for integration of 2D materials. The target substrate may optionally include pre-formed device structures, interconnects, and/or additional adhesive layers to facilitate bonding or integration. The target substrate may be planar or non-planar, rigid or flexible. Further, the adhesive layer has an adhesion to the target substrate that is greater than the adhesion of the 2D material to the growth substrate. In some embodiments, a chemical bond is formed between the adhesion layer and the target substrate. In some embodiments, a van der Waals bond is formed between the adhesion layer and the target substrate. However, this van der Waals bond is stronger than a growth substrate-2D material van der Waals bond.

The method also includes removing the growth substrate, at 708. Thus, at least a portion of the 2D material is transferred from the growth substrate to the target substrate. In some embodiments, at least 70%, at least 80%, at least 90%, or at least 95% of the 2D material is transferred to the target substrate. For example, the growth substrate may be polished or otherwise ground down, or etched to be removed.

Fabrication of the electronic device is completed, at 710. For example, the transistors or other structures using the 2D material(s) may be formed. In addition, other 2D materials may be transferred to the device for subsequent layers as part of 710. Thus, the desired electronic device(s) may be formed. In some embodiments, for example formation of a gate-all-around electronic device, 710 may involve a large number of substeps and multiple repeats of steps 702, 704, 706, and/or 708.

For example, FIGS. 8A-8P are diagrams depicting an embodiment of electronic device 800 formed using transferred 2D materials during fabrication. For clarity, FIGS. 8A-8P are not to scale and some components may not be shown. FIGS. 8A-8P may be considered to depict formation of device 800 using method 700. FIG. 8A depicts device 800 after 702. Thus, 2d material 830 has been provided on growth substrate 802. Growth substrate 802 may be analogous to growth substrate 102. In some embodiments, 2d material is a 2d TMC that may have the properties (e.g., thickness, grain size, and/or electrical properties) described herein. Thus, 2d material 830 is analogous to 2d material 130. Metallization 832 and 834 have been provided on 2D material 830, at 802. For example, metal 832 and 834 may be evaporated or otherwise deposited on 2D material 830.

FIG. 8B depicts electronic device 800 after adhesive layer 820 has been formed at 704. Thus, adhesive layer 820 may have been spin coated or otherwise formed on 2D material 830. Adhesive layer 820 may be analogous to adhesive layer 120. FIG. 8C depicts electronic device 800 after bonding to target substrate 810, at 706. This may occur using a wafer bonder. Substrate 810 is analogous to substrate 110. FIG. 8D depicts electronic device 800 after growth substate 802 has been decoupled or delaminated from 2D material 830, at 708.

FIGS. 8E-8P depict device 800 during formation using 710. FIG. 8E depicts electronic device 800 after mask 840 has been formed. Mask 840 includes apertures that may be used to etch the underlying adhesive layer 820. In some embodiments, mask 840 is a photoresist mask that may be formed of PMMA. FIG. 8F depicts device 800 after a portion of adhesive layer 820 under 2D material 830 (which will form the channel of the device) has been etched. Thus, adhesive layer portions 820’ under metallization 832 and 834 remain. FIG. 8G depicts device 800 after mask 840 has been removed. A gate all around transistor is desired to be formed. Thus, FIG. 8H depicts device 800 after insulator 850 and gate 860 have been provided. Insulator 850 may be a high dielectric constant material. For example, insulator 850 may be provided via atomic layer deposition (ALD). Metal gate 860 may be formed by depositing and patterning a metal layer.

FIG. 8I depicts device 800 after stop layer 862 has been provided. Stop layer 862 may be spin coated (i.e., spun on), deposited, grown, or otherwise provided on insulator 850 and gate 860. In some embodiments, stop layer 862 is polished (e.g., using CMP) or otherwise planarized to provide a substantially flat surface. FIG. 8J depicts device 800 after adhesive layer 870 has been provided. Adhesive layer 870 is analogous to adhesive layer 820 and adhesive layer 140. In some embodiments, adhesive layer 870 may be spun on or otherwise provided on stop layer 862. In some embodiments, adhesive layer 870 may undergo a planarization (e.g., a CMP) in order to provide a more even, flatter surface.

FIG. 8K depicts device 800 with an additional 2D material 830’ that has been prepared for use in a gate-all-around structure. Thus, 2D material 830’ has been grown on growth substrate 802’. Metallization 832’ and 834’ as well as adhesive layer 820’’ have been provided. Growth substrate 802’, 2D material 830’, metallization 832’ and 834’ and adhesive layer 820’’ are analogous to growth substrate 802, 2D material 830, metallization 832 and 834, and adhesive layer 820. Thus, these structures may have been formed using 702 and 704 of method 700.

FIG. 8L depicts device 800 after bonding of adhesive layer 820’’ to adhesive layer 870 and removal of growth substrate 802’. Thus, processes analogous to 706 and 708 may be performed. 2D material 830’ may be used for the channel structure of an additional gate-all-around transistor. Thus, FIG. 8M depicts device 800 after mask 872 has been formed. Mask 872 may be analogous to mask 840. FIG. 8N depicts device 800 after a portion of adhesive layer 820’’ exposed by mask 872 has been etched. Thus, adhesive layer portions 820’’’ remain. Adhesive layer portions 820’’’ are analogous to adhesive layer portions 820’. Thus, the desired portion of 2D material 830’ may be used as a channel for another gate-all around device. FIG. 8O depicts device 800 after mask 872 has been removed. FIG. 8P depicts device 800 after insulator 880 and gate 890 have been formed. Insulator 880 may be a high dielectric constant insulator and may be analogous to insulator 850. Gate 890 may be metal and analogous to gate 860.

Thus, two layers of three-dimensional gate-all-around transistors have been formed using transferred 2D material(s) for the channel. Thus, the benefits of 2D materials, such as 2D TMCs, may be achieved. Thus, performance of electronic device 800 may be improved.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a two-dimensional (2D) material;
a target substrate; and
an adhesive layer between the 2D material and the target substrate;
wherein the 2D material is transferred from a growth substrate to the target substrate, the 2D material having a first adhesion to the adhesive layer and a second adhesion to the growth substrate, the second adhesion being weaker than the first adhesion.

2. The system of claim 1, wherein the 2D material includes at least one of a transition metal dichalcogenide or a transition metal chalcogenide.

3. The system of claim 1, wherein the growth substrate includes sapphire.

4. The system of claim 1, wherein the adhesive layer includes at least one of an insulator, a metal, a polymer, or a semiconductor.

5. The system of claim 4, wherein the adhesive layer includes at least one of benzocyclobutene (BCB), amorphous boron nitride (aBN), HfO₂ SiO₂ Al₂O₃ or a metal.

6. The system of claim 4, wherein the adhesive layer includes a plurality of layers.

7. The system of claim 4, wherein the adhesive layer is spun on, deposited on, or grown on the 2D material while the 2D material is on the growth substrate.

8. The system of claim 1, further comprising:
an additional adhesive layer on the target substrate, the additional adhesive layer being spun on, deposited on, or grown on the target substrate.

9. The system of claim 8, wherein the adhesive layer and the additional adhesive layer include different materials.

10. The system of claim 8, wherein the adhesive layer and the additional adhesive layer include a particular material.

11. An integrated circuit, comprising:
a plurality of electronic devices, each of the plurality of electronic devices including a source, a drain, and a channel layer for the source and the drain, the channel layer including a two-dimensional (2D) material;
wherein an adhesive layer is between the 2D material and a target substrate of the integrated circuit, the 2D material being transferred from a growth substrate to the target substrate, the 2D material having a first adhesion to the adhesive layer and a second adhesion to the growth substrate, the second adhesion being weaker than the first adhesion.

12. The integrated circuit of claim 11, wherein the integrated circuit includes at least one of a processing unit or a memory.

13. The integrated circuit of claim 11, wherein the target substrate includes a plurality of layers fabricated on an underlying substrate, the adhesive layer being proximate to a top layer of the plurality of layers.

14. The integrated circuit of claim 11, wherein the 2D material includes at least one of a transition metal dichalcogenide or a transition metal chalcogenide, the growth substrate includes sapphire, and the adhesive layer includes at least one of benzocyclobutene (BCB), amorphous boron nitride (aBN), HfO₂ SiO₂ Al₂O₃ or a metal.

15. A method, comprising:
providing an adhesive layer on a two-dimensional (2D) material, the 2D material being provided on a growth substrate;
bonding the adhesive layer to a target substrate, the adhesive layer being between the 2D material and the target substrate, the 2D material having a first adhesion to the adhesive layer and a second adhesion to the growth substrate, the second adhesion being weaker than the first adhesion;
removing the growth substrate such that at least a portion of the 2D material is transferred from the growth substrate to the target substrate.

16. The method of claim 15, wherein the 2D material includes at least one of a transition metal dichalcogenide or a transition metal chalcogenide, wherein the growth substrate includes sapphire, and wherein the adhesive layer includes at least one of an insulator, a metal, a polymer, or a semiconductor.

17. The method of claim 16, wherein the adhesive layer includes at least one of benzocyclobutene (BCB), amorphous boron nitride (aBN), HfO₂ SiO₂ Al₂O₃ or a metal.

18. The method of claim 16, wherein the bonding the adhesive layer further includes:
bonding the adhesive layer to an additional adhesive layer on the target substrate.

19. The method of claim 16, wherein the providing the adhesive layer further includes at least one of spinning, depositing, or growing the adhesive layer on the 2D material while the 2D material is on the growth substrate.

20. The method of claim 16, further comprising:
forming at least one electronic device including at least a portion of the 2D material.
